(19) United States
(12) Patent Application Publication
(10) Pub. No.: US 2008/0094258 A1
(43) Pub. Date: Apr. 24, 2008

(54) ELECTRONIC SYSTEM WITH USER-OPERABLE KEYS AND CAPABILITY OF PROMPTING KEYS BEING TOUCHED

(76) Inventor: Ta-Yuan Lee, Taoyuan (TW)

Correspondence Address: HOFFMAN WARNICK & D'ALESSANDRO, LLC, 75 STATE STREET, 14TH FLOOR, ALBANY, NY, 12207, US

(21) Appl. No.: 11/837,697

(22) Filed: Aug. 13, 2007

(30) Foreign Application Priority Data
Oct. 20, 2006 (TW) 095138912

(51) Int. Cl. H03M 11/04

(52) U.S. Cl. 341/22

(57) ABSTRACT

The invention discloses an electronic system with a plurality of user-operable keys and capability of prompting the keys being touched. An electronic system, according to a preferred embodiment of the invention, comprises a user input device, a prompting device, and a processor. The user input device includes the plurality of user-operable keys. The processor is electrically coupled to the user-operable keys and the prompting device respectively. The processor selectively generates a corresponding prompting signal or a corresponding key signal based on the key-in action of one of the keys. When the corresponding prompting signal is transmitted to the prompting device, the prompting device generates a corresponding prompt according to a corresponding prompt. When the corresponding key signal is generating, the processor then executes an input instruction of the key.

### BACKGROUND OF THE INVENTION

1. Field of the Invention

The invention relates to an electronic system with a plurality of user-operable keys and with the capability of prompting the keys being touched by users. More particularly, the invention relates to an electronic system which provides a prompting method by using sound, images, or vibration to prompt users to operate keys.

2. Description of the Prior Art

As the pace of life changes, modern people emphasize more and more on speed and efficiency. Research results show that modern people rely more and more on electronic products with characteristics of convenient communication. Therefore, domestic and international companies both continue to stretch themselves in updating and designing various products to satisfy different demands of consumers. Currently, the most popular electronic product is an integrated product that has various functions integrating communication, entertainment, picture taking, business, and the like. However, since most of the companies always focus on the look and functions of products, an important characteristic of product, humanity, is disappearing little by little.

There are many contradictions between current electronic products and humane design, and one of the contradictions is the presentation of keys on electronic product. In various presentations of keys on electronic products, the most inhumane design is the presentation of keys on mobile phone. Recently, since various mobile phones have been developed for the goal of thin-and-light, the size of mobile phone has been constantly reduced or even compressed, resulting in the empty feeling in the hand and difficulty in operation. “Ultra-thin type” mobile phones have advantages of being light and portable, but the thickness of the keys decreases with the reducing thickness of phones, causing inconvenience in operating the keys by users. When the user wants to select a function or key in data by pressing a plurality of keys, he/she cannot recognize different keys clearly by touch; thus, some undesired keys may be pressed at the same time.

Referring to FIG. 1, FIG. 1 is a schematic diagram illustrating an electronic system 1 according to the prior art. For old people or people with low vision, they always cannot easily recognize different keys by sight or touch due to the tight arrangement of keys 10 of the electronic system 1 and reduced thickness, so undesired keys will be pressed and keyed in. Although some electronic products may have keys with specific thickness arranged in a looser manner and have recognizable gap between different keys, vision-impaired people still need additional tool to operate the keys.

Therefore, the main scope of the invention is to provide an electronic system with user-operable keys and capability of prompting the keys being touched to solve the aforesaid problems. In other words, according to the electronic system of the invention, the keys with prompting function can provide visual or audio prompting for old people or vision-impaired people while operating keys.

### SUMMARY OF THE INVENTION

According to a first preferred embodiment of the invention, an electronic system comprises a user input device, a sensing device, a prompting device, and a processor. The user input device comprises a plurality of user-operable keys. The sensing device is configured to sense one of the user-operable keys being touched by a user and to further generate a corresponding sensing signal in response to the touch of the key. The processor generates a corresponding key signal in response to the key-in action of one of the keys and then executes the input instruction of the key. The processor is electrically coupled to the sensing device and the prompting device respectively. Afterward, the processor generates and outputs a prompting signal to the prompting device in response to the corresponding sensing signal generated by the sensing device. The prompting device generates a corresponding prompt according to the prompting signal.

According to a second preferred embodiment of the invention, an electronic system comprises a user input device, a prompting device, and a processor. The user input device comprises a plurality of user-operable keys. The processor is electrically coupled to the keys and the prompting device respectively. The processor selectively generates a corresponding prompting signal or a corresponding key signal based on the operation of keying-in of one of the keys. Afterward, when the corresponding prompting signal is transmitted to the prompting device, the prompting device generates a corresponding prompt according to the prompting signal. When the corresponding key signal is generating, the processor then executes an input instruction of the key.

According to a third preferred embodiment of the invention, a control method is used for controlling a plurality of user-operable keys of an electronic system. In this embodiment, the sensing device of each of the keys comprises a respective touch sensor and a respective switch. When a user touch one of the keys, the sensor of the key will sense the touch of the key, and then it generates and outputs a corresponding sensing signal to a processor. The processor generates and outputs a corresponding signal to a prompting device in response to the corresponding sensing signal. The prompting device displays an enlarged font of the key, broadcasts the pronunciation of the key, or vibrates based on a vibrating signal in response to the corresponding prompting signal. The switch of the key is switched on by pressing the key, so as to generate and output a switch signal to the processor. The processor then generates a corresponding key signal in response to the corresponding switch signal and executes the input instruction of the key.

In another embodiment, each of the user-operable keys comprises a respective semi-press switch and a respective full-press switch. When a user presses one of the keys half way, the semi-press switch of the key is switched on to enable a processor to generate and output a corresponding prompting signal. When the user fully presses the key, the full-switch of the key is switched on to generate and output a corresponding switch signal.

According to a fourth preferred embodiment of the invention, a control method is used for controlling a plurality of user-operable keys of an electronic system. Each of the user-operable keys comprises a respective switch. This embodiment takes the duration of press as the control method. In this embodiment, when a user presses one of the keys, and the duration of the press is shorter than a predetermined period, the processor will generate and output a corresponding prompting signal to a prompting device in response to the press of the key. Afterward, the prompting device displays an enlarged font of the key, broadcasts the pronunciation of the key, or vibrates based on a vibrating signal in response to the corresponding prompting signal. When the user presses one of the keys and the duration of the press is longer than the predetermined period, the processor will generate a corresponding key signal in response to the press of the key and will then execute the input instruction of the key.

Another embodiment takes how many times of press as the control method. In this embodiment, when a user presses one of the keys once in a predetermined period, the processor will generate and output a corresponding prompting signal to a prompting device. When the user presses one of the keys a second time in the predetermined period, the processor will generate a corresponding key signal and will then execute the input instruction of the key.

The advantage and spirit of the invention may be understood by the following recitations together with the appended drawings.

### BRIEF DESCRIPTION OF THE APPENDED DRAWINGS

FIG. 1 is a schematic diagram illustrating an electronic system according to the prior art.

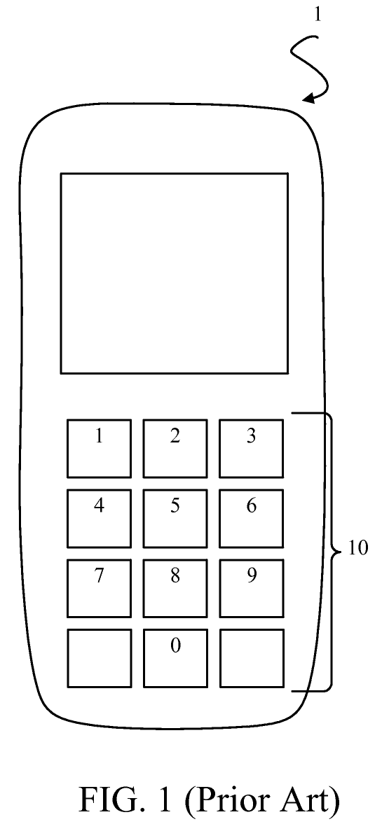

FIG. 2A is a schematic diagram illustrating an electronic system according to a first preferred embodiment of the invention.

FIG. 2B is a functional block diagram illustrating the electronic system according to the first preferred embodiment of the invention.

FIG. 2C is a sectional view illustrating one user-operable key of the electronic system according to another embodiment of the invention.

FIG. 3A is a functional block diagram illustrating an electronic system according to a second preferred embodiment of the invention.

FIG. 3B is another functional block diagram illustrating the electronic system according to the second preferred embodiment of the invention.

FIG. 4 is a flow chart showing a control method according to a third preferred embodiment of the invention.

FIG. 5A is a flow chart showing a control method according to a fourth preferred embodiment of the invention.

FIG. 5B is a flow chart showing another control method according to the fourth preferred embodiment of the invention.

### DETAILED DESCRIPTION OF THE INVENTION

The scope of the invention is to provide an electronic system with user-operable keys and capability of prompting keys being touched. Particularly, the invention relates to electronic system which provides a prompting method by using sound, images, or vibration to prompt users to operate keys. The characteristics, spirit, advantages, and user-friendliness of the invention will be depicted by the following preferred embodiments.

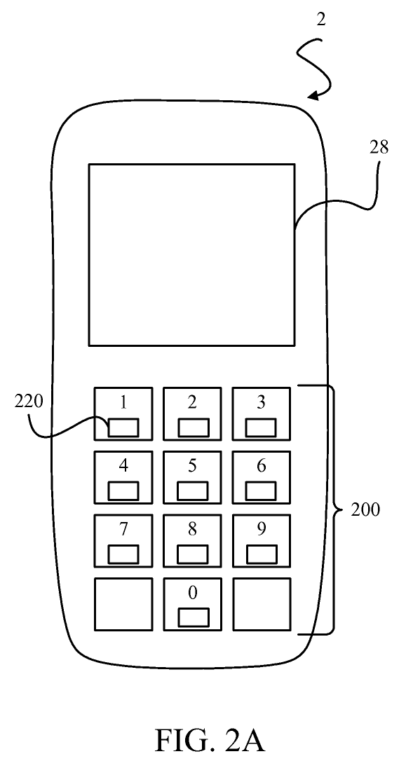

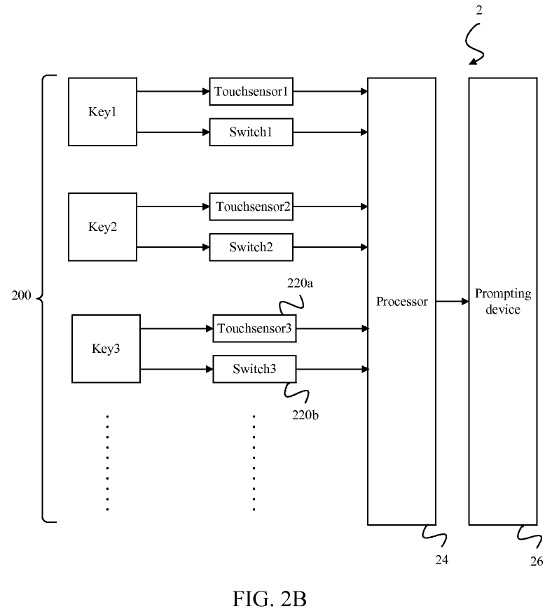

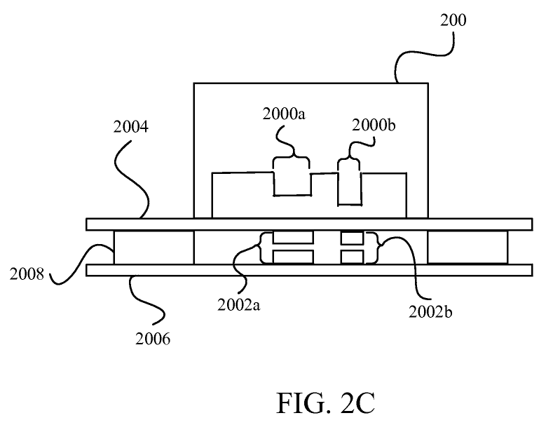

Referring to FIG. 2A and FIG. 2B, FIG. 2A is a schematic diagram illustrating an electronic system 2 according to a first preferred embodiment of the invention. FIG. 2B is a functional block diagram illustrating the electronic system 2 according to the first preferred embodiment of the invention. The electronic system 2 comprises a user input device (not shown), a sensing device (not shown), a prompting device 26, and a processor 24. The user input device comprises a plurality of user-operable keys 200. Each of the user-operable keys 200 comprises a respective key cap (not shown). The electronic system 2 further comprises a plurality of touch sensors 220a. Each touch sensor 220a is disposed on a corresponding key cap and is used for sensing whether a user has touched the corresponding key pad. When the sensing device senses one of the keys 200 being touched by the user, the sensing device further generates a corresponding sensing signal in response to the touch of the key 200. The electronic system 2 further comprises a plurality of switches 220b. Each of the switches 220b corresponds to one of the key caps and is used for detecting whether the corresponding key cap is pressed. If the corresponding key cap is pressed, the switch generates a corresponding switch signal in response to the press of the key cap of the key 200. The processor 24 generates a corresponding key signal in response to the press of one of the keys 200 and executes the input instruction of the key 200. The processor 24 is electrically coupled to the sensing device and the prompting device 26 respectively. In response to the corresponding sensing signal generated by the sensing device, the processor 24 generates and outputs a prompting signal to the prompting device 26, such that the prompting device 26 generates a corresponding prompt according to the prompting signal. The user can determine whether to continue follow-up key-in action of the key 200 according to the corresponding prompt. The prompting device 26 can be a display 28, a speaker, or a vibrator. If the prompting device 26 is a display, the prompting device 26 will display an image relating to the corresponding prompting signal. If the prompting device 26 is a speaker, the prompting device 26 will broadcast an audio relating to the corresponding prompt signal. If the prompting device 26 is a vibrator, the prompting device 26 will vibrate at least once based on a vibrating signal.

In an embodiment, the prompting device 26 is the display 28. In response to a corresponding sensing signal, the processor 24 generates a corresponding prompting signal and then transmits the corresponding prompting signal to the display 28. The display 28 comprises a display controller. In response to the prompting signal, the display controller generates a corresponding display signal to drive the display 28 to display the corresponding prompt. The display signal is an image signal.

For example, when the user only puts his/her finger lightly down on the surface of one of the user-operable keys 200, one of the touch sensors 220a of the key 200 will generate and output a sensing signal to the processor 24 in response to the touch of the key. Afterward, the processor 24 generates and outputs a corresponding prompting signal to the display 28 in response to the corresponding sensing signal. In response to the corresponding prompting signal, the display 28 displays an enlarged font of the key 200, controls the speaker to broadcast the pronunciation of the key 200, or vibrates based on a vibrating signal. When the user takes his/her finger off the surface of the key, the displayed enlarged font of the key 200 is cleared. When the user presses one of the user-operable keys 200, a switch 220b of the key 200 is switched on to generate and output a corresponding switch signal to the processor 24 in response to the press of the key. Afterward, the processor 24 generates a corresponding key signal in response to the corresponding switch signal and executes the input instruction of the key 200. Take key “2” as an example. When the user only puts one finger on “2”, the sensor senses the touch of the finger and then generates and outputs a corresponding sensing signal to the processor 24. The processor 24 generates and outputs a corresponding prompting signal to the display 28 in response to the corresponding sensing signal. The display displays an enlarged font of “2”, controls the speaker to broadcast the pronunciation of “2”, or vibrates based on a vibrating signal. When the user takes his/her finger off the surface of key “2”, the displayed enlarged font of “2” is cleared. However, when the user presses “2”, a switch of “2” is switched on to generate and output a corresponding switch signal to the processor 24. The processor 24 generates a corresponding key signal in response to the corresponding switch signal and executes the input instruction of “2”. Similarly, when the user only puts his/her finger on “3”, the processor 24 generates and outputs a corresponding prompting signal. When the user presses “3”, the processor 24 generates a corresponding key signal and executes the input instruction of “3”. Therefore, each of the user-operable keys 200 can selectively generate a corresponding prompting signal or a corresponding key signal according to different key-in modes.

Referring to FIG. 2C, FIG. 2C is a sectional view illustrating one user-operable key 200 of the electronic system 2 according to another embodiment of the invention. Each of the user-operable keys 200 of the electronic system 2 comprises a respective full-press touch pillar 2000a and a respective semi-press touch pillar 2000b. There is a switch layer under the user-operable keys 200. The switch layer comprises a first soft-film layer 2004, a second soft-film layer 2006, and a space layer 2008. The space layer 2008 is placed between the first soft-film layer 2004 and the second soft-film layer 2006. Each of the user-operable keys 200 further comprises a full-press switch and a semi-press switch. The full-press switch comprises two full-press switch contacts 2002a. The semi-press switch comprises two semi-press switch contacts 2002b. The first soft-film layer 2004 and the second soft-film layer 2006 respectively comprise one of the two full-press switch contacts 2002a, one of the two semi-press switch contacts 2002b, and a corresponding circuit (not shown). The two full-press switch contacts 2002a correspond to the full-press touch pillar 2000a. The two semi-press switch contacts 2002b correspond to the semi-press touch pillar 2000b. When the user presses one of the keys 200 half way, the semi-press touch pillar 2000b will first press the semi-press switch contact 2002b on the first soft-film layer 2004 and then enable the semi-press switch contact 2002b to contact the semi-press switch contact 2002b on the second soft-film layer 2006. The processor 24 further detects a semi-press signal due to the connection between the two contacts via the circuit. The processor 24 generates and outputs a corresponding prompting signal to the display 28 in response to the corresponding semi-press signal generated by the sensing device. Afterward, the display 28 displays an enlarged font of the key 200, controls the speaker to broadcast the pronunciation of the key 200, or vibrates based on a vibrating signal. When the user releases the key soon after pressing the key half way, the displayed enlarged font of the key 200 is cleared. When the user fully presses one of the keys 200, the full-press touch pillar 2000a presses the full-press switch contact 2002a on the first soft-film layer 2004 and then enables the full-press switch contact 2002a to contact the full-press switch contact 2002a on the second soft-film layer 2006. The processor 24 further detects a full-press signal due to the connection between the two contacts via the circuit. The processor 24 generates a corresponding key signal in response to the full-press signal and executes the input instruction of the key. Take key “2” as an example. When the user presses “2” half way, the processor 24 generates and outputs a corresponding prompting signal to the display 28. The display 28 displays an enlarged font of “2”, controls the speaker to broadcast the pronunciation of “2”, or vibrates based on a vibrating signal, so as to indicate the key “2” is being pressed by the user. When the user releases the key “2” soon after pressing the key “2” half way, the displayed enlarged font of “2” is cleared. When the user fully presses “2”, the processor 24 generates a corresponding key signal and executes the input instruction of “2”. Similarly, when the user presses “3” half way, the processor 24 generates and outputs a corresponding prompting signal. When the user fully presses “3”, the processor 24 generates a corresponding key signal and executes the input instruction of “3”. Therefore, each of the user-operable keys 200 can selectively generate a corresponding prompting signal or a corresponding key signal according to different key-in pressure.

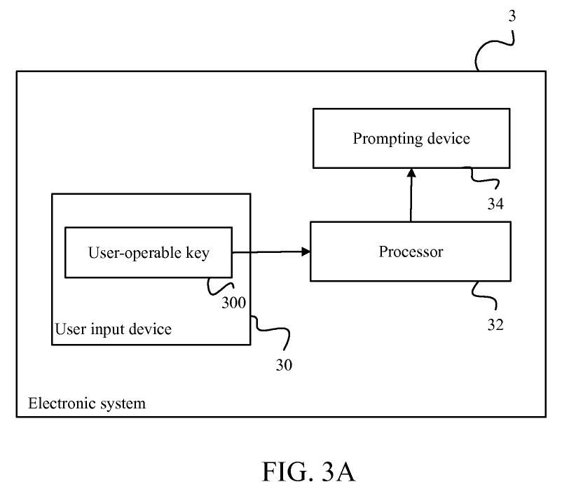

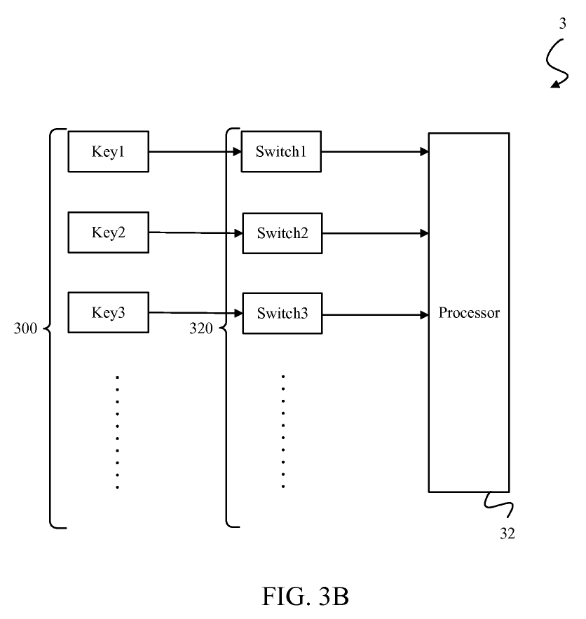

Referring to FIG. 3A and FIG. 3B, FIG. 3A is a functional block diagram illustrating an electronic system 3 according to a second preferred embodiment of the invention. FIG. 3B is another functional block diagram illustrating the electronic system 3 according to the second preferred embodiment of the invention. The electronic system 3 comprises a user input device 30, a prompting device 34, and a processor 32. The user input device 30 comprises a plurality of user-operable keys 300. Each of the user-operable keys 300 comprises a respective switch 320. The switch 320 is electrically coupled to the processor 32. The switch 320 selectively generates and transmits a switch signal to the processor 32 according to the key-in action of one key 300. The processor 32 is electrically coupled to the prompting device 34. The processor 32 selectively generates a corresponding prompting signal or a corresponding key signal based on the key-in action of one of the keys 300 and executes the input instruction of the key. The corresponding prompting signal is transmitted to the prompting device 34. The prompting device 34 generates a corresponding prompt according to the prompting signal. When the corresponding key signal is generating, the processor 32 then executes the input instruction of the key.

In an embodiment, the processor 32 selectively generates a corresponding prompting signal or a corresponding key signal based on the duration of the key-in action of the key 300. Take key “2” as an example. When the user presses key “2”, and the duration of the press is shorter than a predetermined period, such as one second, the processor 32 will detect a sensing signal based on the press of “2” and then generates and outputs a corresponding prompting signal to the prompting device 34. The prompting device 34 displays an enlarged font of “2”, controls the speaker to broadcast the pronunciation of “2”, or vibrates based on a vibrating signal. The displayed enlarged font of “2” will be cleared after being displayed for a span of time. When the user presses “2” for at least one second, the processor 32 will detect a switch signal, generates a corresponding key signal, and then executes the input instruction of key “2”. Similarly, when the user presses the key “3” for less than one second, the processor 32 generates and outputs a corresponding prompting signal. When the user presses “3” for at least one second, the processor 32 generates a corresponding key signal and executes the input instruction of key “3”. Therefore, each of the user-operable keys selectively generates a corresponding prompting signal or a corresponding key signal according to the duration of the key-in action.

In another embodiment, the processor 32 can selectively generate a corresponding prompting signal or a corresponding key signal based on how many times the key 300 is pressed. When the user first presses one key 300, such as “2”, the switch 320b which corresponds to the key cap of “2” generates and outputs a signal to a processor in response to the press of the user. The processor 32 determines the signal as a sensing signal and then generates and outputs a corresponding prompting signal to the prompting device 34. The prompting device 34 then displays an enlarged font of “2”, controls the speaker to broadcast the pronunciation of “2”, or vibrates based on a vibrating signal. If the user does not press any key later, the displayed enlarged font of “2” will be cleared after being displayed for a span of time. If the user presses “2” again, the processor 32 determines the signal of the switch as a switch signal, generates a corresponding key signal, and then executes the input instruction of “2”. If the user does not press key “2” later but presses another key, such as “3”, the processor 32 determines the signal of the switch of key “3” as a sensing signal and then generates and outputs a corresponding prompting signal to the prompting device 34. Afterward, the prompting device 34 will clear the displayed enlarged font of “2” and then displays the enlarged font of “3”, controls the speaker to broadcast the pronunciation of “3”, or vibrates based on a vibrating signal. Therefore, each of the user-operable keys 300, which may be pressed by the user, can be prompted according to the double key-in mode, so as to prevent the wrong key 300 from being keyed in.

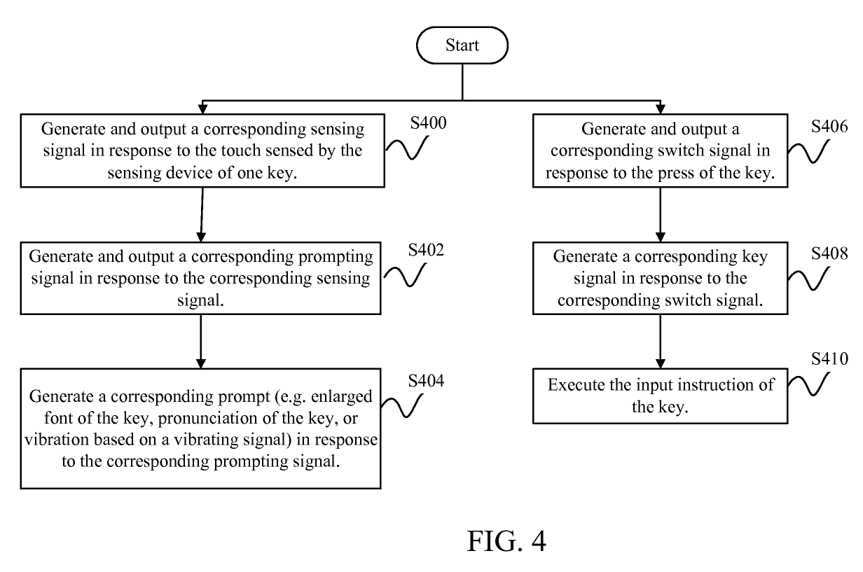

Referring to FIG. 4, FIG. 4 is a flow chart showing a control method according to a third preferred embodiment of the invention. The control method is used for controlling a plurality of user-operable keys of an electronic system. According to the aforesaid third preferred embodiment, the control method of the invention comprises the following steps.

In the beginning, step S400 is performed to generate and output a corresponding sensing signal in response to the touch sensed by the sensing device of a key. Afterward, step S402 is performed to generate and output a corresponding prompting signal in response to the corresponding sensing signal. Step S404 is then performed to generate a corresponding prompt (e.g. enlarged font of the key, pronunciation of the key, or vibration based on a vibrating signal) in response to the corresponding prompting signal. Step S406 is then performed to generate and output a corresponding switch signal in response to the press of the key. Step S408 is then performed to generate a corresponding key signal in response to the corresponding switch signal. Finally, step S410 is performed to execute the input instruction of the key.

In an embodiment, the sensing device of each of the user-operable keys comprises a respective touch sensor and a respective switch. The touch sensor is used for sensing the touch of one key to generate and output a sensing signal. The switch of the key is switched on by the press of the key to generate and output a switch signal.

In another embodiment, the sensing device of each of the keys comprises a respective semi-press switch and a respective full-press switch. The semi-press switch comprises a semi-press touch pillar disposed below the key cap and two corresponding semi-press switch contacts. The full-press switch comprises a full-press touch pillar disposed below the key cap and two corresponding full-press switch contacts. When one key is pressed half way, the semi-press touch pillar will press the two corresponding semi-press switch contacts. After the two corresponding semi-press switch contacts are switched on by the semi-press touch pillar, a processor generates and outputs a prompting signal. When the key is fully pressed, the full-press touch pillar will press the two corresponding full-press switch contacts. After the two corresponding full-press switch contacts are switched on by the full-press touch pillar, a switch signal will be generated and outputted.

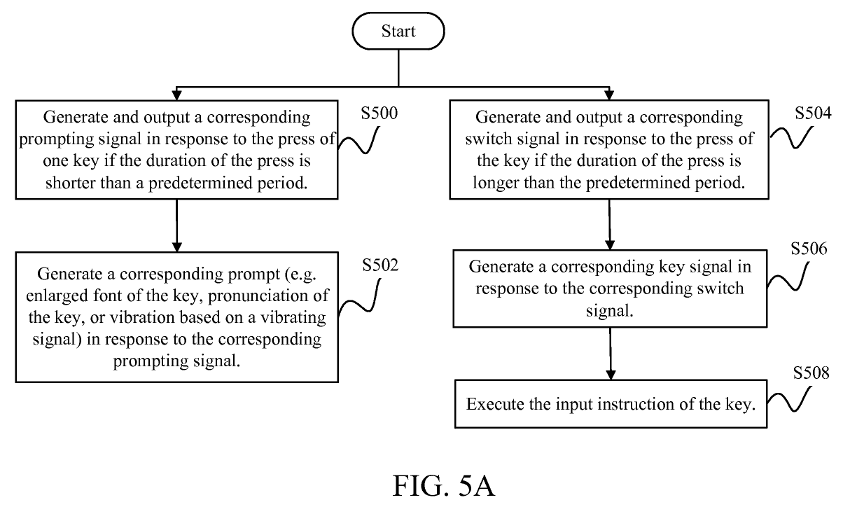

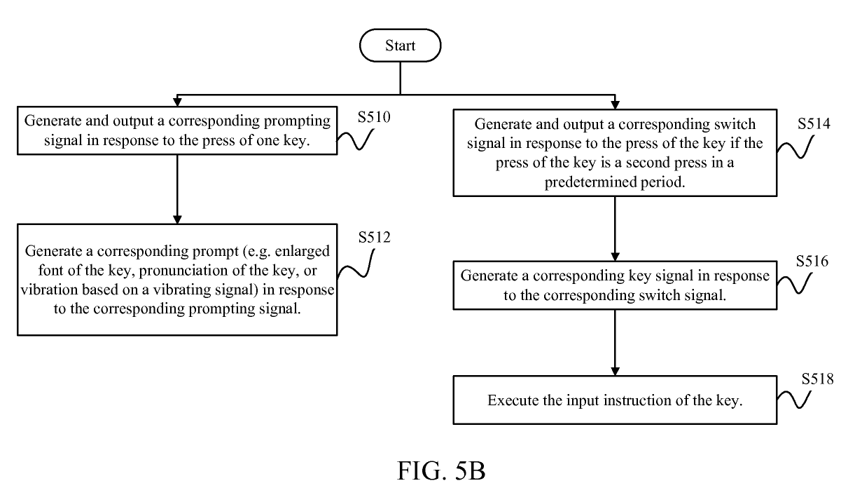

Referring to FIG. 5A, FIG. 5A is a flow chart showing a control method according to a fourth preferred embodiment of the invention. The control method is used for controlling a plurality of user-operable keys of an electronic system. According to the aforesaid fourth preferred embodiment, the control method of the invention comprises the following steps.

In the beginning, step S500 is performed to generate and output a corresponding prompting signal in response to the press of one key if the duration of the press is shorter than a predetermined period. Afterward, step S502 is performed to generate a corresponding prompt (e.g. enlarged font of the key, pronunciation of the key, or vibration based on a vibrating signal) in response to the corresponding prompting signal. Step S504 is then performed to generate and output a corresponding switch signal in response to the press of the key if the duration of the press is longer than the predetermined period. Step S506 is then performed to generate a corresponding key signal in response to the corresponding switch signal. Finally, step S508 is then performed to execute the input instruction of the key.

Each of the user-operable keys comprises a respective switch. According to the duration of the press of one key, the switch selectively generates a switch signal or enables a processor to generate a corresponding prompting signal. The predetermined period can be set by a user.

Referring to FIG. 5B, FIG. 5B is a flow chart showing another control method according to the fourth preferred embodiment of the invention. The control method is also used for controlling a plurality of user-operable keys of an electronic system. According to the aforesaid fourth preferred embodiment, the control method of the invention comprises the following steps.

In the beginning, step S510 is performed to generate and output a corresponding prompting signal in response to the press of one key. Afterward, step S512 is performed to generate a corresponding prompt (e.g. enlarged font of the key, pronunciation of the key, or vibration based on a vibrating signal) in response to the corresponding prompting signal. Step S514 is then performed to generate and output a corresponding switch signal in response to the press of the key if the press of the key is a second press in a predetermined period. Step S516 is then performed to generate a corresponding key signal in response to the corresponding switch signal. Finally, step S518 is performed to execute the input instruction of the key.

Each of the user-operable keys comprises a respective switch. According to how many times one key is pressed in a predetermined period, the switch selectively generates a switch signal or enables a processor to generate a corresponding prompting signal. The predetermined period can be set by a user.

According to the aforesaid preferred embodiments of the invention, the electronic system of the invention can be clearly understood. When a user, such as old people or vision-impaired people, touches one key of the electronic system, the electronic system prompts the user by providing a prompt comprising sound, images, or vibration, so as to achieve the objective of prompting the user when operating the electronic system.

With the example and explanations above, the features and spirits of the invention will be hopefully well described. Those skilled in the art will readily observe that numerous modifications and alternations of the device may be mad while retaining the teaching of the invention. Accordingly, the above disclosure should be construed as limited only by the metes and bounds of the appended claims.

What is claimed is:

1. An electronic system, comprising:
a user input device comprising a plurality of user-operable keys;
a sensing device being configured to sense one of the user-operable keys being touched by a user, and further to generate a corresponding sensing signal in response to the touch of the key;
a prompting device; and
a processor, in response to the key-in action of one of the keys, for generating a corresponding key signal and executing the input instruction of the key, the processor being electrically coupled to the sensing device and the prompting device respectively, the processor, in response to the corresponding sensing signal generated by the sensing device, being used for generating and outputting a prompting signal to the prompting device, the prompting device generating a corresponding prompt according to the prompting signal.

2. The electronic system of claim 1, wherein the prompting device is one selected from a group consisting of a display, a speaker, and a vibrator.

3. The electronic system of claim 1, wherein the prompting device is a display, the corresponding prompting signal is transmitted to the display, and the display comprises a display controller, in response to the prompting signal, for generating a corresponding display signal to drive the display to display the corresponding prompt.

4. The electronic system of claim 1, wherein each of the user-operable keys comprises one respective key cap, the sensing device comprises a sensing circuit and a plurality of touch sensors electrically coupled to the sensing circuit, each touch sensor corresponds to one of the key caps and is configured to sense the corresponding key cap which is touched by the user, and the sensing circuit generates the corresponding sensing signal in response to the sensed touch of the key cap of the key.

5. The electronic system of claim 1, wherein each of the user-operable keys comprises one respective key cap, the sensing device comprises a sensing circuit and a plurality of semi-press switches electrically coupled to the sensing circuit, each semi-press switch corresponds to one of the key caps and is configured to be switched on when the corresponding key cap is pressed half way, and the sensing circuit correspondingly generates the corresponding sensing signal.

6. An electronic system, comprising:
a user input device comprising a plurality of user-operable keys;
a prompting device; and
a processor, electrically coupled to the user-operable keys and the prompting device respectively, for selectively generating a corresponding prompting signal or a corresponding key signal based on operation of key-in of one of the keys, wherein when the corresponding prompting signal being transmitted to the prompting device, the prompting device generating a corresponding prompt according to the prompting signal, when the corresponding key signal is generating, the processor then executing an input instruction of the key.

7. The electronic system of claim 6, wherein the prompting device is one selected from a group consisting of a display, a speaker, and a vibrator.

8. The electronic system of claim 6, wherein the prompting device is a display, the corresponding prompting signal is transmitted to the display, and the display comprises a display controller, in response to the prompting signal, for generating a corresponding display signal to drive the display to display the corresponding prompt.

9. The electronic system of claim 6, wherein the processor selectively generates the corresponding prompting signal or the corresponding key signal based on the duration of the key-in action of the key, when the duration of key-in is shorter than a predetermined period, the processor generates the corresponding prompting signal, and when the duration of key-in is longer than the predetermined period, the processor generates the corresponding key signal and executes the input instruction of the key.

10. The electronic system of claim 6, wherein the processor selectively generates the prompting signal or the corresponding key signal based on once key-in or double key-in of the key, the processor generates the corresponding prompting signal according to once key-in of the key during a predetermined period, and the processor generates the corresponding key signal and executes the input instruction of the key according to double key-in of the key during the predetermined period.

11. The electronic system of claim 6, wherein the electronic system is a mobile phone and the input device is the number keys which are disposed on the mobile phone.

12. A control method for controlling a plurality of user-operable keys of an electronic system, comprising steps of:
generating and outputting a corresponding sensing signal in response to the touch of one key;
generating and outputting a corresponding prompting signal in response to the corresponding sensing signal;
generating a corresponding prompt of the key in response to the corresponding prompting signal;
generating and outputting a corresponding switch signal in response to the press of the key;
generating a corresponding key signal in response to the corresponding switch signal; and
executing an input instruction of the key.

13. The control method of claim 12, wherein the prompt is one selected from a group consisting of enlarged font of a key, pronunciation of a key, and vibration of a key.

14. The control method of claim 12, wherein the key comprises a touch sensor, when the key is touched, the touch sensor of the key senses the touch of the key and then generates the sensing signal, the key further comprises a switch, when the key is pressed, the switch of the key is switched on and then generates the switch signal.

15. The control method of claim 12, wherein the key comprises a semi-press switch and a full-press switch, when the key is half pressed, the semi-pressed switch of the key is switched on and then generates the prompting signal, when the key is fully pressed, the full-pressed switch of the key is switched on and then generates the switch signal

16. A control method for controlling a plurality of user-operable keys of an electronic system, each of the user-operable keys comprising a respective switch, the control method comprising steps of:
generating and outputting a corresponding prompting signal in response to a first press of one key;
generating a corresponding prompt of the key in response to the corresponding prompting signal;
generating and outputting a corresponding switch signal in response to a second press of the key;
generating a corresponding key signal in response to the corresponding switch signal; and
executing an input instruction of the key.

17. The control method of claim 16, wherein the prompt is one selected from a group consisting of enlarged font of a key, pronunciation of a key, and vibration of a key.

18. The control method of claim 16, further comprising comparing duration of pressing the key with a predetermined period, if the duration of pressing the key is shorter than the predetermined period, the press being the first press, then generating the corresponding prompting signal, if the duration of pressing the key is longer the predetermined period, the press being the second press, then generating the switch signal.

19. The control method of claim 16, wherein the press of the key is selectively regarded as the first press or the second press based on how many times the key is pressed during a predetermined period, so as to generate the prompting signal or the switch signal correspondingly.

20. The control method of claim 19, wherein the press of the key is regarded as the first press if the key is pressed once during the predetermined period, and then the prompting signal is generated, wherein the press of the key is regarded as the second press if the key has been pressed twice during the predetermined period, and then the switch signal is generated, and the input instruction of the key is executed.
